(19) United States
(12) Patent Application Publication
(10) Pub. No.: US 2013/0333750 A1
(43) Pub. Date: Dec. 19, 2013

(54) THIN FILM SOLAR CELL AND MANUFACTURING METHOD THEREOF

(71) Applicant: NEXPOWER TECHNOLOGY CORPORATION, Taichung City (TW)

(72) Inventors: CHIA-LING LEE, Tainan City (TW); CHIEN-CHUNG BI, Taichung City (TW)

(73) Assignee: NEXPOWER TECHNOLOGY CORPORATION, Taichung City (TW)

(21) Appl. No.: 13/847,327

(22) Filed: Mar. 19, 2013

(30) Foreign Application Priority Data
Jun. 14, 2012 (TW) 101121426

(51) Int. Cl. H01L 31/0376

(52) U.S. Cl. CPC H01L 31/0376
USPC 136/255; 438/87

(57) ABSTRACT

The present invention discloses a thin-film solar cell and the manufacturing method thereof. A thin-film solar cell includes a substrate, a P-type layer, an interface layer, an I-type amorphous silicon layer, an I-type absorbing layer, an N-type layer and an electrode layer. The P-type is disposed on the substrate. The interface layer is disposed on the P-type layer. The I-type amorphous silicon layer is disposed on the interface layer. The I-type absorbing layer is disposed on the I-type amorphous silicon layer. The N-type layer is disposed on the I-type absorbing layer. The electrode layer is disposed on the N-type layer. Wherein, the I-type absorbing layer is thicker than 20% the I-type amorphous silicon layer, and the interface layer is thinner than 20% of the I-type amorphous silicon layer.

### CROSS-REFERENCE TO RELATED APPLICATION

This application claims the benefit of Taiwan Patent Application No. 101121426, filed on Jun. 14, 2012, in the Taiwan Intellectual Property Office, the disclosure of which is incorporated herein in its entirety by reference.

### BACKGROUND OF THE INVENTION

1. Field of the Invention

The present invention relates to a thin film solar cell, and more particularly to the thin film solar cell and its manufacturing method capable of enhancing the overall current and improving the interfacial film quality to increase the fill factor of the thin film solar cell.

2. Description of the Related Art

In recent years, the development of renewable energy and green energy has become a global trend due to environmental protection and resource depletion issues. It is noteworthy that solar energy is a natural un-depleted source of energy with the advantage of a uniform allocation of resources, and solar cells have features such as pollution-free, high-safety and long life, so that the solar photovoltaic industry attracts attention at the market.

At present, commonly used solar cells includes crystalline silicon solar cells and thin film solar cells, wherein the thin film solar cell has the advantages of a lower cost, a smaller thickness and less electric power loss. However, present existing thin film solar cells generally have the problem of low conversion efficiency, hence, methods such as changing the materials and structure of semiconductors or the way they are stacked in series are used to improve the conversion efficiency of the thin film solar cell.

The conventional thin film solar cell comprises a substrate and a P-I-N semiconductor layer. The semiconductor layer comprises a P-type layer, an I-type layer and an N-type layer sequentially formed on the substrate by spluttering or chemical deposition. Although the technology of producing the thin film solar cell is mature, yet the fill factor and the current of the thin film solar cell still require further improvements. To improve the aforementioned problems, it is necessary to provide a thin film solar cell capable of enhancing the photoelectric conversion efficiency.

### SUMMARY OF THE INVENTION

Therefore, it is a primary objective of the present invention to provide a thin film solar cell and a manufacturing method thereof in order to improve the fill factor and current of the thin film solar cell.

To achieve the aforementioned objective, the present invention provides a thin film solar cell comprising a substrate, a P-type layer, an I-type amorphous silicon layer, an I-type absorbing layer, an N-type layer and an electrode layer. The P-type layer is disposed on the substrate. The I-type amorphous silicon layer is disposed on the P-type layer. The I-type absorbing layer is disposed on the I-type amorphous silicon layer. The N-type layer is disposed on the I-type absorbing layer. The electrode layer is disposed on the N-type layer. Wherein, the I-type absorbing layer has a band gap smaller than 1.8 eV, and the I-type absorbing layer has a band gap smaller than that of the I-type amorphous silicon layer to increase the overall optical absorption of the I-type absorbing layer to enhance the current of the thin film solar cell, and the I-type absorbing layer has a thickness greater than 20% of the thickness of the I-type amorphous silicon layer.

Preferably, the I-type absorbing layer is made of a material including microcrystalline silicon, microcrystalline silicon germanium or amorphous silicon germanium.

Preferably, the present invention further comprises an interface layer disposed between the P-type layer and the I-type amorphous silicon layer, and the interface layer has a thickness smaller than 20% of the thickness of the I-type amorphous silicon layer.

Preferably, the interface layer has a photoconductivity greater than 10−4 (Ω-cm)−1 and a dark conductivity smaller than 10−11(Ω-cm)−1.

Preferably, the N-type layer has a microcrystalline silicon photovoltaic structure disposed thereon.

Preferably, the N-type layer has an amorphous silicon photovoltaic structure and a microcrystalline silicon photovoltaic structure sequentially disposed thereon.

Another objective of the present invention is to provide a thin film solar cell comprising a substrate, a P-type layer, a first interface layer, an I-type amorphous silicon layer, an N-type layer and an electrode layer. The P-type layer is disposed on the substrate. The first interface layer is disposed on the P-type layer. The I-type amorphous silicon layer is disposed on the first interface layer. The N-type layer is disposed on the I-type amorphous silicon layer. The electrode layer is disposed on the N-type layer. Wherein, the first interface layer can enhance the fill factor of the thin film solar cell by improving the interfacial film quality of the I-type amorphous silicon layer, and the first interface layer has a thickness smaller than 20% of the thickness of the I-type amorphous silicon layer, and the first interface layer has a photoconductivity greater than 10−4(Ω-cm)−1 and a dark conductivity smaller than 10−11(Ω-cm)−1.

Preferably, the present invention further comprises a second interface layer, disposed on the I-type amorphous silicon layer, and the second interface layer having a thickness smaller than 20% of the thickness of the I-type amorphous silicon layer.

Preferably, the first interface layer and the second interface layer are made of microcrystalline silicon, microcrystalline silicon germanium or amorphous silicon germanium.

Preferably, second interface layer has a photoconductivity greater than 10−4(Ω-cm)−1 and a dark conductivity smaller than 10−11(Ω-cm)−1.

Preferably, the N-type layer has a microcrystalline silicon photovoltaic structure disposed thereon.

Preferably, the N-type layer has an amorphous silicon photovoltaic structure and a microcrystalline silicon photovoltaic structure sequentially disposed thereon.

A further objective of the present invention is to provide a thin film solar cell comprising a substrate, a P-type layer, an I-type amorphous silicon layer, a first interface layer, an N-type layer and an electrode layer. The P-type layer is disposed on the substrate. The I-type amorphous silicon layer is disposed on the P-type layer. The first interface layer is disposed on the I-type amorphous silicon layer. The N-type layer is disposed on the first interface layer. The electrode layer is disposed on the N-type layer. Wherein, the first interface layer enhance the fill factor of the thin film solar cell by improving the interfacial film quality of the I-type amorphous silicon layer, and the first interface layer has a thickness smaller than 20% of the thickness of the I-type amorphous silicon layer, and the first interface layer has a photoconductivity greater than 10−4(Ω-cm)−1 and a dark conductivity smaller than 10−11(Ω-cm)−1.

Preferably, the present invention further comprises a second interface layer disposed on the P-type layer, and the second interface layer having a thickness smaller than 20% of the thickness of the I-type amorphous silicon layer.

Preferably, the first interface layer and the second interface layer are made of microcrystalline silicon, microcrystalline silicon germanium or amorphous silicon germanium.

Preferably, the second interface layer has a photoconductivity greater than 10−4(Ω-cm)−1 and a dark conductivity smaller than 10−11(Ω-cm)−1.

Preferably, the N-type layer has a microcrystalline silicon photovoltaic structure disposed thereon.

Preferably, the N-type layer has an amorphous silicon photovoltaic structure and a microcrystalline silicon photovoltaic structure sequentially disposed thereon.

in addition, the present invention further provides a thin film solar cell manufacturing method comprising the steps of: providing a substrate; setting a P-type layer on the substrate; setting an I-type amorphous silicon layer on the P-type layer; setting an N-type layer on the I-type amorphous silicon layer; and setting an electrode layer on the N-type layer; wherein an I-type absorbing layer or an interface layer is further set between the I-type amorphous silicon layer and the N-type layer, or another interface layer is set between the P-type layer and the I-type amorphous silicon layer, and the I-type absorbing layer has a band gap smaller than 1.8 eV, and the interface layer has a photoconductivity greater than 10−4(Ω-cm)−1 and a dark conductivity smaller than 10−11(Ω-cm)−1.

Preferably, the I-type absorbing layer and the interface layer are made of microcrystalline silicon, microcrystalline silicon germanium or amorphous silicon germanium.

Preferably, the I-type absorbing layer has a thickness greater than 20% of the thickness of the I-type amorphous silicon layer, and the interface layer has a thickness smaller than 20% of the thickness of the I-type amorphous silicon layer.

Preferably, the method further comprises a step of setting a microcrystalline photovoltaic structure on the N-type layer.

Preferably, the method further comprises a step of setting an amorphous silicon photovoltaic structure and a microcrystalline silicon photovoltaic structure sequentially on the N-type layer.

In summation, the thin film solar cell and the manufacturing method of the present invention have one or more of the following advantages:

(1) In the thin film solar cell, an I-type absorbing layer is added on the I-type amorphous silicon layer, and the I-type absorbing layer has a smaller band gap for absorbing light with a greater range of wavelengths, and the feature of the I-type absorbing layer having a band gap smaller than the band gap of the I-type amorphous silicon layer band gap is harnessed to enhance the overall optical absorption of the absorbing layer and enhance the current of the thin film solar cell,

(2) In the thin film solar cell, a first interface layer is added to the top side or bottom side of the I-type amorphous silicon layer and a second interface layer is added to the top side or bottom side of the I-type amorphous silicon layer, and a first interface layer and a second interface layer are provided for improving the interfacial film of the I-type amorphous silicon layer to enhance the fill factor of the thin film solar cell and the efficiency of the thin film solar cell.

### BRIEF DESCRIPTION OF THE DRAWINGS

FIG. 1 is a schematic view of a thin film solar cell in accordance with a first preferred embodiment of the present invention;

FIG. 2 is a flow chart of a manufacturing method of the thin film solar cell in accordance with the first preferred embodiment of the present invention;

FIG. 3 is a schematic view of a thin film solar cell in accordance with a first implementation mode of the first preferred embodiment of the present invention;

FIG. 4 is a schematic view of a thin film solar cell in accordance with a second implementation mode of the first preferred embodiment of the present invention;

FIG. 5 is a graph that compares currents of a thin film solar cell in accordance with the first preferred embodiment of the present invention;

FIG. 6 is a schematic view of a thin film solar cell in accordance with a second preferred embodiment of the present invention;

FIG. 7 is a flow chart of a manufacturing method of the thin film solar cell in accordance with the second preferred embodiment of the present invention;

FIG. 8 is a schematic view of a thin film solar cell in accordance with a first implementation mode of the second preferred embodiment of the present invention;

FIG. 9 is a schematic view of a thin film solar cell in accordance with a second implementation mode of the second preferred embodiment of the present invention; and

FIG. 10 is a graph that compares various electric properties of a thin film solar cell in accordance with the first preferred embodiment of the present invention.

### DESCRIPTION OF THE PREFERRED EMBODIMENTS

The technical characteristics, contents, advantages and effects of the present invention will be apparent with the detailed description of a preferred embodiment accompanied with related drawings as follows. The drawings are provided for the illustration, and same numerals are used to represent respective elements in the preferred embodiments. It is intended that the embodiments and drawings disclosed herein are to be considered illustrative rather than restrictive. Same numerals are used for representing same respective elements in the drawings.

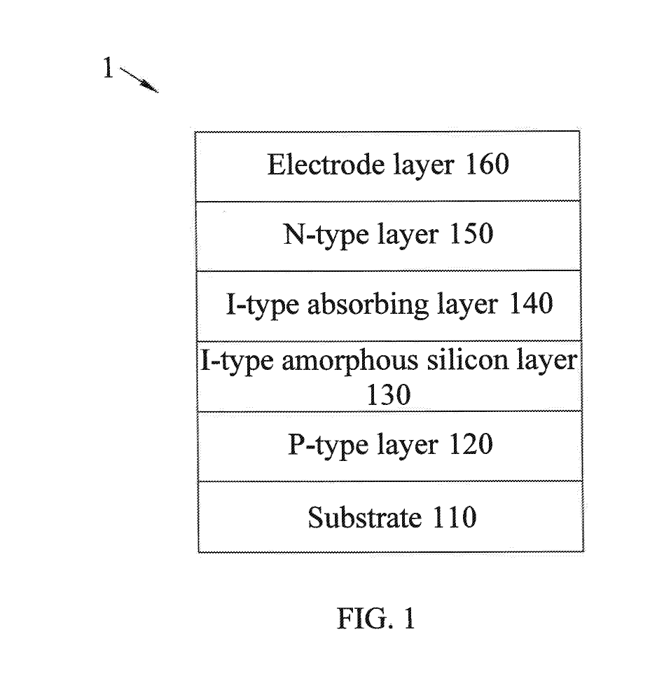

With reference to FIG. 1 for a schematic view of a thin film solar cell in accordance with a first preferred embodiment of the present invention, the thin film solar cell 1 comprises a substrate 110, a P-type layer 120, an I-type amorphous silicon layer 130, an I-type absorbing layer 140, an N-type layer 150 and an electrode layer 160. The substrate 110 is made of a transparent conductive sheet material including but not limited to glass, plastic or acrylic. The P-type layer 120 is disposed on the substrate 110. The I-type amorphous silicon layer 130 is disposed on the P-type layer 120. The I-type absorbing layer 140 is disposed on the I-type amorphous silicon layer 130 and made of a material including but not limited to microcrystalline silicon, microcrystalline silicon germanium or amorphous silicon germanium, and the material has a band gap smaller than 1.8 eV. The N-type layer 150 is disposed on the I-type absorbing layer 140. The electrode layer 160 is disposed on the N-type layer 150. Wherein, the I-type absorbing layer 140 has a thickness greater than 20% of the thickness of the I-type amorphous silicon layer 130.

In this preferred embodiment, the thin film solar cell 1 uses the feature of a smaller band gap of the material giving a greater wavelength range of the absorbed light to enhance the optical absorption. Since the I-type amorphous silicon layer 140 has a band gap of 1.8 eV, and the cutoff wavelength of the absorbed light is approximately equal to 800 nm, therefore the light absorption range of the thin film solar cell 1 can be increased by adding an I-type absorbing layer with a band gap smaller than 1.8 eV into the thin film solar cell 1, and the cutoff wavelength of the absorbed light is greater than 800 nm, so as to enhance the overall current of the thin film solar cell 1.

Particularly, an interface layer (not shown in the figure) be added between the P-type layer 120 and the I-type amorphous silicon layer 130 in this preferred embodiment, and the interface layer has a thickness smaller than 20% of the thickness of the I-type amorphous silicon layer 130, a photoconductivity greater than 10−4(Ω-cm)−1, and a dark conductivity smaller than 10−11(Ω-cm)−1.The interface layer is made of a material including but not limited to microcrystalline silicon, microcrystalline silicon germanium or amorphous silicon germanium. With the added interface layer, the thin film quality of the I-type amorphous silicon layer 130 can be improved to enhance the fill factor or the thin film solar cell 1.

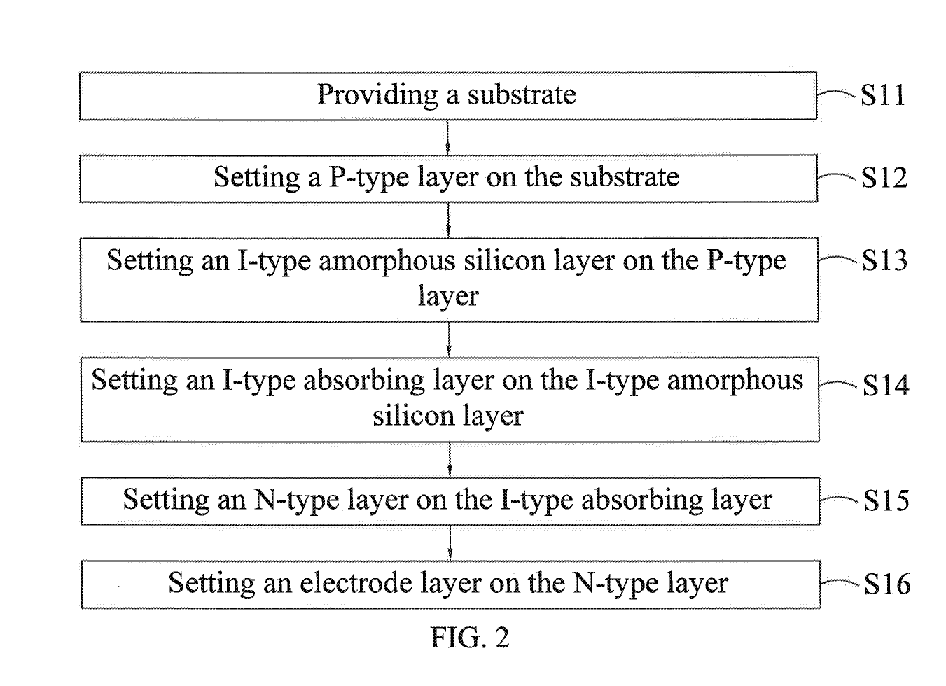

With reference to FIG. 2 for a flow chart of a manufacturing method of the thin film solar cell in accordance with the first preferred embodiment of the present invention, the manufacturing method comprises the following steps.

S11: Providing a substrate, wherein the substrate is made of a transparent conductive sheet material including but not limited to glass, plastic or acrylic.

S12: Setting a P-type layer on the substrate.

S13: Setting an I-type amorphous silicon layer on the P-type layer.

S14: Setting an I-type absorbing layer on the I-type amorphous silicon layer, wherein the I-type absorbing layer is made of a material including but not limited to microcrystalline silicon, microcrystalline, silicon germanium or amorphous silicon germanium, and the material has a band gap smaller than 1.8 eV.

S15: Setting an N-type layer on the I-type absorbing layer.

S16: Setting an electrode layer on the N-type layer, wherein the electrode layer is made of a transparent conductive film or a metal with good electric conductivity, and the I-type absorbing layer has a thickness greater than 20% of the thickness of the I-type amorphous silicon layer.

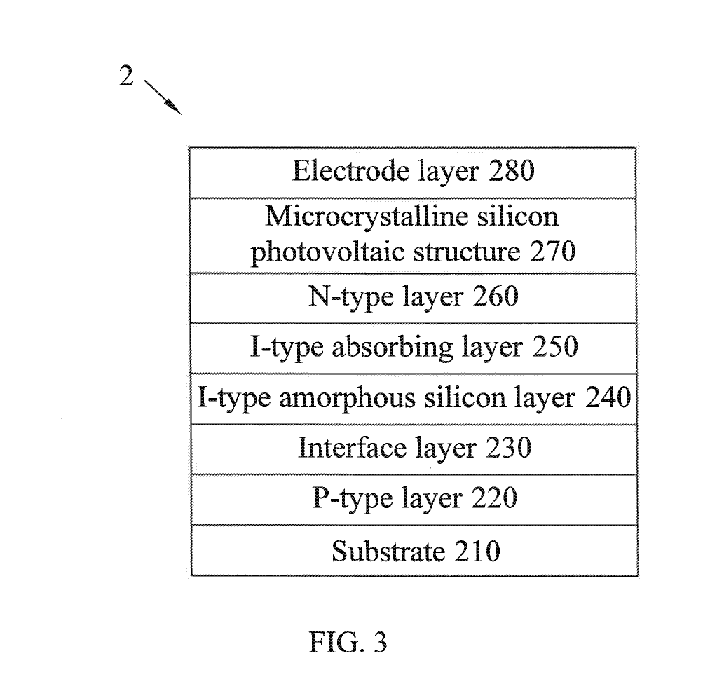

With reference to FIG. 3 for a schematic view of a thin film solar cell in accordance with a first implementation mode of the first preferred embodiment of the present invention, the thin film solar cell 2 comprises a substrate 210, a P-type layer 220, an interface layer 230, an I-type amorphous silicon layer 240, an I-type absorbing layer 250, an N-type layer 260, a microcrystalline silicon photovoltaic structure 270 and an electrode layer 280. The substrate 210 is made of a transparent conductive sheet material including but not limited to glass, plastic or acrylic. The P-type layer 220 is disposed on the substrate 210. The interface layer 230 is disposed on the P-type layer 220 and has a photoconductivity greater than 10−4(Ω-cm)−1 and a dark conductivity smaller than 10−11(Ω-cm)−1. The I-type amorphous silicon layer 240 is disposed on the interface layer 230. The I-type absorbing layer 250 is disposed on the I-type amorphous silicon layer 240 and made of a material including but not limited to microcrystalline silicon, microcrystalline silicon germanium or amorphous silicon germanium, and the material has a band gap smaller than 1.8 eV. The N-type layer 260 is disposed on the I-type absorbing layer 250. The microcrystalline silicon photovoltaic structure 270 is disposed on the N-type layer 260. The electrode layer 280 is disposed on the microcrystalline silicon photovoltaic structure 270. The electrode layer 280 is made of a transparent conductive film or a metal with good electric conductivity. Wherein, the interface layer 230 has a thickness smaller than 20% of the thickness of the I-type amorphous silicon layer 240, and the I-type absorbing layer 250 has a thickness greater than 20% of the thickness of the I-type amorphous silicon layer 240.

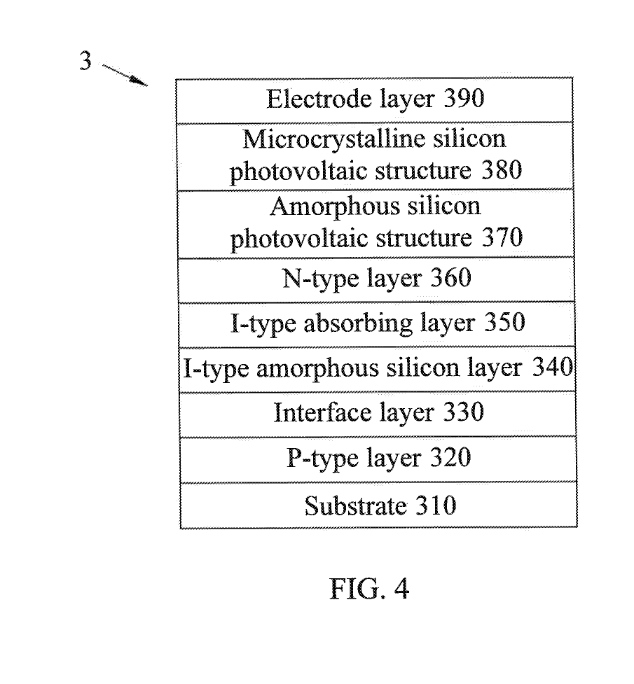

With reference to FIG. 4 for a schematic view of a thin film solar cell in accordance with a second implementation mode of the first preferred embodiment of the present invention, the thin film solar cell 3 comprises a substrate 310, an P-type layer 320, an interface layer 330, an I-type amorphous silicon layer 340, an I-type absorbing layer 350, an N-type layer 360, an amorphous silicon photovoltaic structure 370, a microcrystalline silicon photovoltaic structure 380 and an electrode layer 390. The substrate 310 is made of a transparent conductive sheet material including but not limited to glass, plastic or acrylic. The P-type layer 320 is disposed on the substrate 310. The interface layer 330 is disposed on the P-type layer 320 and has a photoconductivity greater than 10−4(Ω-cm)−1 and a dark conductivity smaller than 10−11(Ω-cm)−1. The I-type amorphous silicon layer 340 is disposed on the interface layer 330. The I-type absorbing layer 350 is disposed on the I-type amorphous silicon layer 340 and made of a material including but not limited to microcrystalline silicon, microcrystalline silicon germanium or amorphous silicon germanium, and the material has a band gap smaller than 1.8 eV. The N-type layer 360 is disposed on the I-type absorbing layer 350. The amorphous silicon photovoltaic structure 370 is disposed on the N-type layer 360. The microcrystalline silicon photovoltaic structure 380 is disposed on the amorphous silicon photovoltaic structure 370. The electrode layer 390 is disposed on the microcrystalline silicon photovoltaic structure 380. The electrode layer 390 is made of a transparent conductive film or a metal with good electric conductivity. Wherein, the interface layer 330 has a thickness smaller than 20% of the thickness of the I-type amorphous silicon layer 340, and the I-type absorbing layer 350 has a thickness greater than 20% of the thickness of the I-type amorphous silicon layer 340. Further, the microcrystalline silicon photovoltaic structure includes a P-type layer, an I-type microcrystalline silicon layer and an N-type layer. The amorphous silicon photovoltaic structure includes a P-type layer, I-type amorphous silicon layer and an N-type layer. In this preferred embodiment, the thin film solar cells of the first and second implementation modes of the first preferred embodiment are stacked to form one or more photovoltaic structures, and the thin film solar cell of the first preferred embodiment is used as a basic structure to form the stacking thin film solar cell to improve the photoelectric conversion efficiency of the thin film solar cell. Therefore, the solar cell structure of the first preferred embodiment is used as the basic structure, but the type and quantity of photovoltaic structures formed on the basic structure are not limited to those as described in the first and second implementation modes only.

In general, the photoelectric conversion efficiency (Eff) is measured by referencing three numeral values, respectively: fill factor (FF), open-circuit voltage (Voc) and short-circuit current density, wherein the three numeric values are directly proportional to the photoelectric conversion efficiency. Compared with the prior art, the thin film solar cell of the first preferred embodiment of the present invention has a current greater than the current of the conventional thin film solar cell.

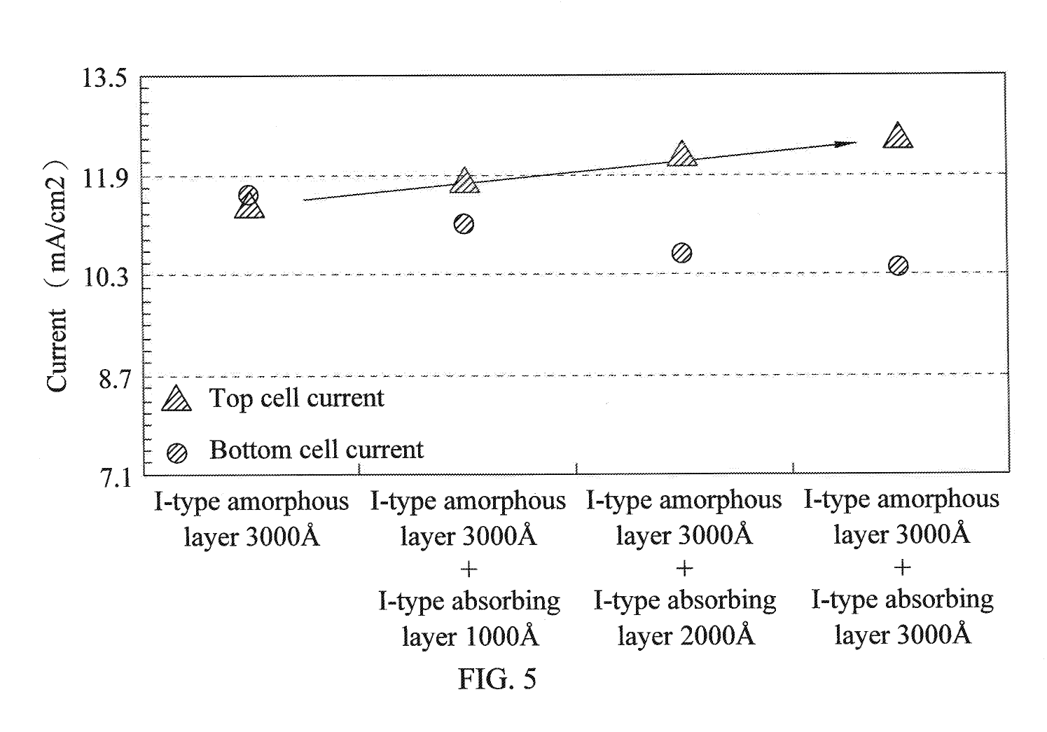

With reference to FIG. 5 for a graph that compares currents between a conventional thin film solar cell and a thin film solar cell with a microcrystalline silicon photovoltaic structure stacked on the I-type amorphous silicon layer and a thickness fixed at 3000 angstroms in accordance with the first preferred embodiment of the present invention, a thin film solar cell only having an I-type amorphous silicon layer, a thin film solar cell having an I-type amorphous silicon layer of 3000 angstroms stacked with an I-type absorbing layer of 1000 angstroms, a thin film solar cell having an I-type amorphous silicon layer of 3000 angstroms stacked with an I-type absorbing layer of 2000 angstroms, and thin film solar cell having an I-type amorphous silicon layer of 3000 angstroms stacked with an I-type absorbing layer of 3000 angstroms are compared. In FIG. 5, when the I-type absorbing layer is added into the thin film solar cell, the current of the top cell is increased significantly, and thus showing that the I-type absorbing layer added into the thin film solar cell can enhance the current of the thin film solar cell.

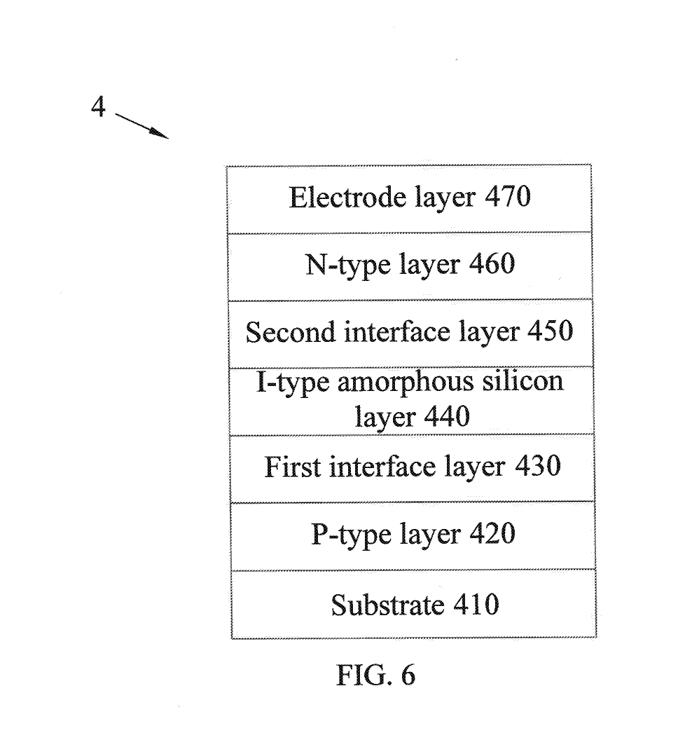

With reference to FIG. 6 for a schematic view of a thin film solar cell in accordance with a second preferred embodiment of the present invention, the thin film solar cell 4 comprises a substrate 410, a P-type layer 420, a first interface layer 430, an I-type amorphous silicon layer 440, a second interface layer 450, an N-type layer 460 and an electrode layer 470. The substrate 410 is made of a transparent conductive sheet material including but not limited to glass, plastic or acrylic. The P-type layer 420 is disposed on the substrate 410. The first interface layer 430 is disposed on the P-type layer 420. The I-type amorphous silicon layer 440 is disposed on the first interface layer 430. The second interface layer 450 is disposed on the I-type amorphous silicon layer 440. The N-type layer 460 is disposed on the second interface layer 450. The electrode layer 470 is disposed on the N-type layer 460. The electrode layer 470 is made of a transparent conductive film or a metal with good electric conductivity. Wherein, the first interface layer 430 and the second interface layer 450 have a thickness smaller than 20% of the thickness of the I-type amorphous silicon layer 440, and the first interface layer 430 and the second interface layer 450 are made of a material including but not limited to microcrystalline microcrystalline silicon germanium or amorphous silicon germanium, and the first interface layer 430 and the second interface layer 450 have a photoconductivity greater than 10−4(Ω-cm)−1 and a dark conductivity smaller than 10−11(Ω-cm)−1.

In this preferred embodiment, the thin film solar cell 4 improves the interfacial film quality of the I-type amorphous silicon layer 440 to enhance the fill factor of the thin film solar cell 4 by adding the first interface layer 430 and the second interface layer 450 into the thin film solar cell 4.

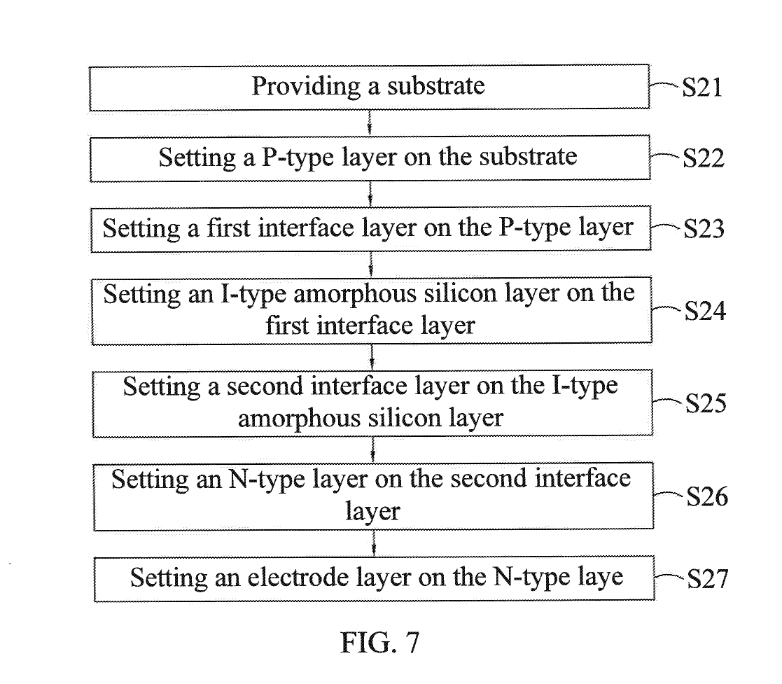

With reference to FIG. 7 for a flow chart of a manufacturing method of the thin film solar cell in accordance with the second preferred embodiment of the present invention, the thin film. solar cell manufacturing method of this preferred embodiment comprises the following steps.

S21: Providing a substrate. The substrate is made of a transparent conductive material including but not limited to glass, plastic or acrylic.

S22: Setting a P-type layer on the substrate.

S23: Setting a first interface layer on the P-type layer.

S24: Setting an I-type amorphous silicon layer on the first interface layer.

S25: Setting a second interface layer on the I-type amorphous silicon layer. Wherein, the first interface layer and the second interface layer are made of a material including but not limited to microcrystalline silicon, microcrystalline silicon germanium or amorphous silicon germanium, and the first interface layer and the second interface layer have a thickness smaller than 20% of the thickness of the I-type amorphous silicon layer, a photoconductivity greater than 10−4(Ω-cm)−1, and a dark conductivity smaller than 10−11(Ω-cm)−1.

S26: Setting an N-type layer on the second interface layer.

S27: Setting an electrode layer on the N-type layer. Wherein, the electrode layer is made of a transparent conductive film or a metal with good electric conductivity.

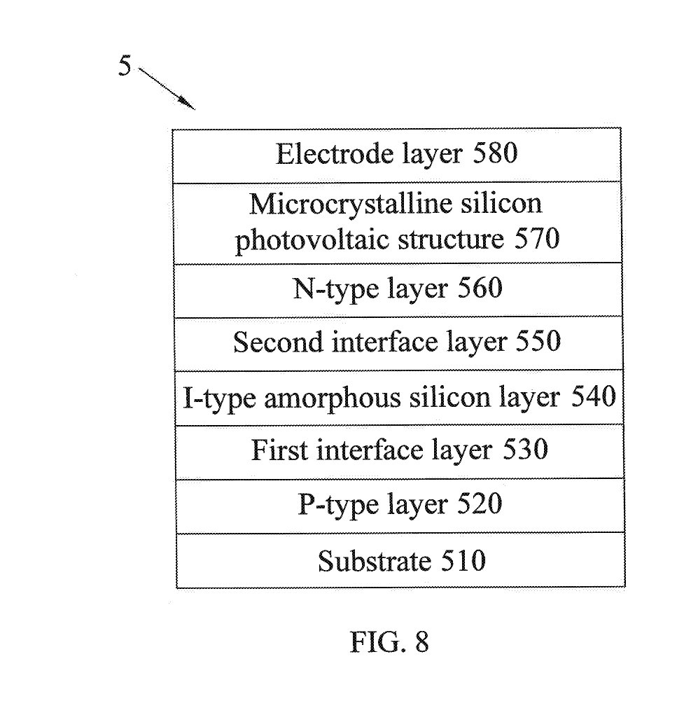

With reference to FIG. 8 for a schematic view of a thin film solar cell in accordance with a first implementation mode of the second preferred embodiment of the present invention, the thin film solar cell 5 comprises a substrate 510, a P-type layer 520, a first interface layer 530, an I-type amorphous silicon layer 540, a second interface layer 550, an N-type layer 560, a microcrystalline silicon photovoltaic structure 570 and an electrode layer 580. The substrate 510 is made of a transparent conductive sheet material including but not limited to glass, plastic or acrylic. The P-type layer 520 is disposed on the substrate 510. The first interface layer 530 is disposed on the P-type layer 520. The I-type amorphous silicon layer 540 is disposed on the first interface layer 530. The second interface layer 550 is disposed on the I-type amorphous silicon layer 540. The N-type layer 560 is disposed on the second interface layer 550. The microcrystalline silicon photovoltaic structure 570 is disposed on the N-type layer 560. The electrode layer 580 is disposed on the microcrystalline silicon photovoltaic structure 570 and made of a transparent conductive film or a metal with good electric conductivity. The first interface layer 530 and the second interface layer 550 are made of a material including but not limited to microcrystalline silicon, microcrystalline silicon germanium or amorphous silicon germanium, and the first interface layer 530 and the second interface layer 550 have a thickness smaller than 20% of the thickness of the I-type amorphous silicon layer 540, a photoconductivity greater than 10−4(Ω-cm)−1, and a dark conductivity smaller than 10−11(Ω-cm)−1.

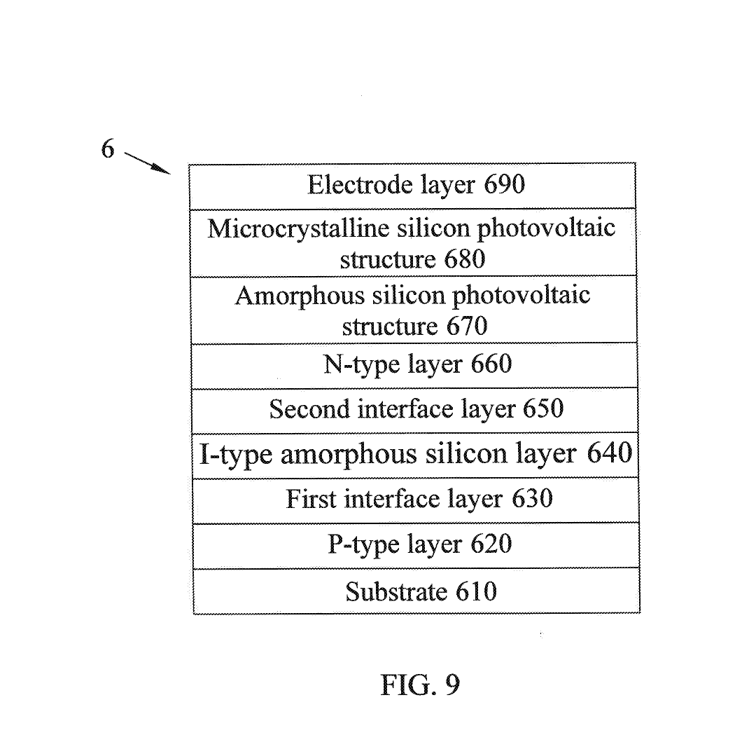

With reference to FIG. 9 for a schematic view of a thin film solar cell in accordance with a second implementation mode of the second preferred embodiment of the present invention, the thin film solar cell 6 comprises a substrate 610, a P-type layer 620, a first interface layer 630, an I-type amorphous silicon layer 640, a second interface layer 650, an N-type layer 660, an amorphous silicon photovoltaic structure 670, a microcrystalline silicon photovoltaic structure 680 and an electrode layer .690. The substrate 610 is made of a transparent conductive sheet material including but not limited to glass, plastic or acrylic. The P-type layer 620 is disposed on the substrate 610. The first interface layer 630 is disposed on the P-type layer 620. The I-type amorphous silicon layer 640 is disposed on the first interface layer 630. The second interface layer 650 is disposed on the I-type amorphous silicon layer 640. The N-type layer 660 is disposed on the second interface layer 650. The amorphous silicon photovoltaic structure 670 is disposed on the N-type layer 660. The microcrystalline silicon photovoltaic structure 680 is disposed on the amorphous silicon photovoltaic structure 670. The electrode layer 690 is disposed on the microcrystalline silicon photovoltaic structure 680 and made of a transparent conductive film or a metal with good electric conductivity. The first interface layer 630 and the second interface layer 650 are made of a material including but not limited to microcrystalline silicon, microcrystalline silicon germanium or amorphous silicon germanium, and the first interface layer 630 and the second interface layer 650 have a thickness smaller than 20% of the thickness of the I-type amorphous silicon layer 640, a photoconductivity greater than 10−4(Ω-cm)−1, and a dark conductivity smaller than 10−11(Ω-cm)−1.

In this preferred embodiment, the thin film solar cells of the first and second implementation modes of the second preferred embodiment are stacked to form one or more photovoltaic structures, and the thin film solar cell of the second preferred embodiment is used as a basic structure to form the stacking thin film solar cell to improve the photoelectric conversion efficiency of the thin film solar cell. Therefore, the solar cell structure of the second preferred embodiment is used as the basic structure, but the type and quantity of photovoltaic structures formed on the basic structure are not limited to those as described in the first and second implementation modes only.

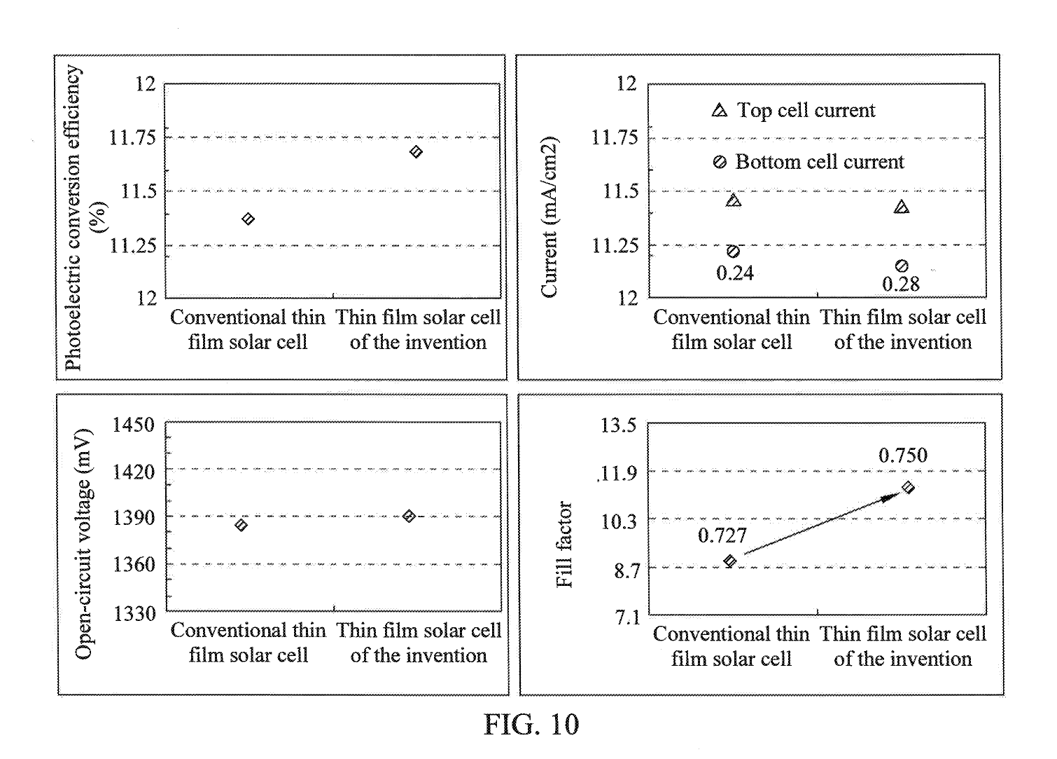

In general, the photoelectric conversion efficiency (Eff) is measured by referencing three numeral values, respectively: fill factor (FF), open-circuit voltage (Voc) and short-circuit current density, wherein the three numeric values are directly proportional to the photoelectric conversion efficiency. The comparison between the prior art and the thin film solar cell of the second preferred embodiment of the present invention shows that the thin film solar cell of the second preferred embodiment of the present invention has a fill factor greater than the fill factor of the conventional thin film solar cell as shown in FIG. 10.

With reference to FIG. 10 for a graph that compares various electric properties including the photoelectric conversion efficiency, the current, the open-circuit voltage and the fill factor between the prior art and a thin film solar cell with two interface layers added in accordance with the first preferred embodiment of the present invention, the numeric value in the graph shows the absolute value difference of the top cell current and the bottom cell current. In FIG. 10, the absolute value difference of the currents of the thin film solar cell is 0.24 mA/cm2, and the absolute value difference of the currents of the thin film solar cell in accordance with the second preferred embodiment of the present invention is 0.28 mA/cm2. The fill factor value of the conventional thin film solar cell is 0.727, and the fill factor value of the thin film solar cell of the second preferred embodiment of the present invention is 0.750. In general, if the difference between the top cell current and the bottom cell current is not large, then the fill factors will not have such a big different, so that the improved fill factor is not resulted from the effect of current matching.

In summation of the description above, the thin film solar cell and the manufacturing method of the present invention adds an I-type absorbing layer with a band gap smaller than 1.8 eV on the I-type amorphous silicon layer of the conventional thin film solar cell, and the feature of the I-type absorbing layer with a hand gap smaller than that of the I-type amorphous silicon layer enhances the optical absorption of the thin film solar cell to enhance the overall current of the thin film solar cell. In addition, the interface layer added to the top side or bottom side of the I-type amorphous silicon layer can improve the interfacial film quality of the I-type amorphous silicon layer to enhance the fill factor of the thin film solar cell.

What is claimed is:

1. A thin film solar cell, comprising:
a substrate;
a P-type layer, disposed on the substrate;
an I-type amorphous silicon layer, disposed on the P-type layer;
an I-type absorbing layer, disposed on the I-type amorphous silicon layer;
an N-type layer, disposed on the I-type absorbing layer; and
an electrode layer, disposed on the N-type layer;
wherein, the I-type absorbing layer has a band gap smaller than 1.8 eV, and the band gap of the I-type absorbing layer smaller than that of the I-type amorphous silicon layer increases the overall optical absorption of the I-type absorbing layer and enhance a current of the thin film solar cell, and the I-type absorbing layer has a thickness greater than 20% of a thickness of the I-type amorphous silicon layer.

2. The thin film solar cell of claim 1, wherein the I-type absorbing layer is made of microcrystalline silicon, microcrystalline silicon germanium or amorphous silicon germanium.

3. The thin film solar cell of claim 1, further comprising an interface layer disposed between the P-type layer and the I-type amorphous silicon layer, and the interface layer has a thickness smaller than 20% of the thickness of the I-type amorphous silicon layer.

4. The thin film solar cell of claim 3, wherein the interface layer has a photoconductivity greater than 10⁻⁴(Ω-cm)⁻¹ and a dark conductivity smaller than 10⁻¹¹(Ω-cm)⁻¹.

5. The thin film solar cell of claim 1, wherein the N-type layer has a microcrystalline silicon photovoltaic structure disposed thereon.

6. The thin film solar cell of claim 1, wherein the N-type layer has an amorphous silicon photovoltaic structure and a microcrystalline silicon photovoltaic structure sequentially disposed thereon.

7. A thin film solar cell, comprising:
a substrate;
a P-type layer, disposed on the substrate;
a first interface layer, disposed on the P-type layer;
an I-type amorphous silicon layer, disposed on the first interface layer;
an N-type layer, disposed on the I-type amorphous silicon layer; and
an electrode layer, disposed on the N-type layer;
wherein the first interface layer enhances a fill factor of the thin film solar cell by improving a interfacial film quality of the I-type amorphous silicon layer, and the first interface layer has a thickness smaller than 20% of the thickness of the I-type amorphous silicon layer, and the first interface layer has a photoconductivity greater than 10⁻⁴(Ω-cm)⁻¹ and a dark conductivity smaller than 10¹¹(Ω-cm)⁻¹.

8. The thin film solar cell of claim 7, further comprising a second interface layer, disposed on the I-type amorphous silicon layer, and the second interface layer having a thickness smaller than 20% of a thickness of the I-type amorphous silicon layer.

9. The thin film solar cell of claim 8, wherein the first interface layer and the second interface layer are made of microcrystalline silicon, microcrystalline silicon germanium or amorphous silicon germanium.

10. The thin film solar cell of claim 8, wherein the second interface layer has a photoconductivity greater than 10⁻⁴(Ω-cm)⁻¹ and a dark conductivity smaller than 10⁻¹¹(Ω-cm)⁻¹.

11. The thin film solar cell of claim 7, wherein the N-type layer has a microcrystalline silicon photovoltaic structure disposed thereon.

12. The thin film solar cell of claim 7, wherein the N-type layer has an amorphous silicon photovoltaic structure and a microcrystalline silicon photovoltaic structure sequentially disposed thereon.

13. A thin film solar cell, comprising:
a substrate;
a P-type layer, disposed on the substrate;
an I-type amorphous silicon layer, disposed on the P-type layer;
a first interface layer, disposed on the I-type amorphous silicon layer;
an N-type layer, disposed on the first interface layer; and
an electrode layer, disposed on the N-type layer;
wherein, the first interface layer enhance a fill factor of the thin film solar cell by improving an interfacial film quality of the I-type amorphous silicon layer, and the first interface layer has a thickness smaller than 20% of a thickness of the I-type amorphous silicon layer, and the first interface layer has a photoconductivity greater than 10⁻⁴(Ω-cm)⁻¹ and a dark conductivity smaller than 10⁻¹¹(Ω-cm)⁻¹.

14. The thin film solar cell of claim 13, further comprising a second interface layer disposed on the P-type layer, and the second interface layer having a thickness smaller than 20% of the thickness of the I-type amorphous silicon layer.

15. The thin film solar cell of claim 14, wherein the first interface layer and the second interface layer are made of microcrystalline silicon, microcrystalline silicon germanium or amorphous silicon germanium.

16. The thin film solar cell of claim 14, wherein the second interface layer has a photoconductivity greater than 10⁻⁴(Ω-cm)⁻¹ and a dark conductivity smaller than 10⁻¹¹(Ω-cm)⁻¹.

17. The thin film solar cell of claim 13, wherein the N-type layer has a microcrystalline silicon photovoltaic structure disposed thereon.

18. The thin film solar cell of claim 13, wherein the N-type layer has an amorphous silicon photovoltaic structure and a microcrystalline silicon photovoltaic structure sequentially disposed thereon.

19. A thin film solar cell manufacturing method, comprising the steps of:
providing a substrate;
setting a P-type layer on the substrate;
setting an I-type amorphous silicon layer on the P-type layer;
setting an N-type layer on the I-type amorphous silicon layer; and
setting an electrode layer on the N-type layer;
wherein an I-type absorbing layer or an interface layer is further set between the I-type amorphous silicon layer and the N-type layer, or another interface layer is set between the P-type layer and the I-type amorphous silicon layer, and the I-type absorbing layer has a band gap smaller than 1.8 eV, and the interface layer has a photoconductivity greater than 10⁻⁴(Ω-cm)⁻¹ and a dark conductivity smaller than 10⁻¹¹(Ω-cm)⁻¹.

20. The thin film solar cell manufacturing method of claim 19, wherein the I-type absorbing layer and the interface layer are made of microcrystalline silicon, microcrystalline silicon germanium or amorphous silicon germanium.

21. The thin film solar cell manufacturing method of claim 19, wherein the I-type absorbing layer has a thickness greater than 20% of a thickness of a I-type amorphous silicon layer, and the interface layer has a thickness smaller than 20% of the thickness of the I-type amorphous silicon layer.

22. The thin film solar cell manufacturing method of claim 19, further comprising the step of setting a microcrystalline silicon photovoltaic structure on the N-type layer.

23. The thin film solar cell manufacturing method of claim 19, further comprising the step of setting an amorphous silicon photovoltaic structure and a microcrystalline silicon photovoltaic structure sequentially on the N-type layer.
